(19) United States
(12) Patent Application Publication
(10) Pub. No.: US 2007/0109875 A1
(43) Pub. Date: May 17, 2007

(54) Data storage method and information processing device using the same

(76) Inventors: Kazuhiko Tanaka, Fujisawa (JP); Makoto Kuwata, Akiruno (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/581,341

(22) Filed: Oct. 17, 2006

(30) Foreign Application Priority Data
Oct. 19, 2005 (JP) 2005-303837

(51) Int. Cl. G11C 7/10

(52) U.S. Cl. 365/189.05

(57) ABSTRACT

A hierarchical-search-based motion vector search, which stores both a non-reduced image and a reduced image in an external memory, has the problem of wasting the external memory capacity and the memory bandwidth. An information processing device according to the present invention exchanges data in a range wider than the memory bus width when a non-reduced image is stored in the external memory and selects whether or not the data is exchanged when the data is read. This allows two types of data, non-reduced and reduced, to be read from the data of the non-reduced image stored in the external memory.

### BACKGROUND OF THE INVENTION

The present invention relates to an information processing device, in which an LSI and a memory are installed, that executes processing such as image processing.

In digital broadcasting and a DVD that are widely used today, moving images are compressed before being transferred or recorded. This is because the data amount of non-compressed digital moving images becomes extremely large. The most popular compression algorism is MPEG2. Although there are other algorithms such as H.264, they are similar in that both intra-frame data compression and inter-frame data compression are used.

Intra-frame data compression reduces the data amount by reducing redundant data using the characteristics of images. On the other hand, inter-frame data compression reduces the data amount by exploiting the similarities between successive frames.

When inter-frame compression is applied to a moving video, motion prediction is performed to find how much an object in a frame moves. Motion prediction is processing for finding to which part of the reference frame the target image area is most similar. During motion prediction, the evaluation value representing the similarity between a part of the reference frame and the target image area is calculated sequentially for the neighboring areas in the reference frame to calculate the coordinates where the similarity is the highest. Because this processing requires high calculation performance, several methods for reducing the processing amount have been proposed.

One of the proposed methods is the hierarchical search. As disclosed in JP-A-10-320175, this search method thins both the target image area and the reference frame and, using the thinned area and the thinned reference frame, searches the reference frame for the most similar area. After that, the method searches the neighboring areas in the reference frame corresponding to the most similar area again using the image area and the reference frame that are not thinned.

### SUMMARY OF THE INVENTION

The hierarchical search requires two types of image data, non-thinned and thinned, in an external storage device. This leads to an increase in the space required in the external storage and results in an increase in cost. In addition, images are stored in the external device via the bus between the external storage device and the LSI. In this case, when two types of image data, non-thinned and thinned, are stored in the external storage device, the bandwidth of the bus is used up by transferring these two types of data and the system performance is decreased.

The present invention exchanges data positions in an area wider than the bus width when access is made to the external memory to make it possible to create a thinned image from a non-thinned image stored in the external memory without wasting the bus bandwidth.

### BRIEF DESCRIPTION OF THE DRAWINGS

FIG. 1 is a diagram showing a system in a first embodiment.

FIG. 2 is a diagram showing a video receiving circuit in the first embodiment.

FIG. 3 is a diagram showing a motion prediction circuit (coarse search) in the first embodiment.

FIG. 4 is a diagram showing a motion prediction circuit (fine search) in the first embodiment.

FIG. 5 is a diagram showing an in-frame compression circuit in the first embodiment.

FIG. 6 is a diagram showing an external memory control circuit in the first embodiment.

FIG. 7 is a diagram showing a display control circuit in the first embodiment.

FIG. 8 is a diagram showing a read data mapping circuit in the first embodiment.

FIG. 9 is a diagram showing patterns used to write into the flip-flops in the read data mapping circuit in the first embodiment.

FIG. 10 is a diagram showing patterns used to read from the flip-flops in the read data mapping circuit in the first embodiment.

FIG. 11 is a diagram showing a write data mapping circuit in the first embodiment.

FIG. 12 is a diagram showing patterns used to write into the flip-flops in the write data mapping circuit in the first embodiment.

FIG. 13 is a diagram showing patterns used to read from the flip-flops in the write data mapping circuit in the first embodiment.

FIG. 14 is a diagram showing a system in a second embodiment.

FIG. 15 is a diagram showing an external memory control circuit in the second embodiment.

FIG. 16 is a diagram showing a read data mapping circuit in the second embodiment.

FIG. 17 is a diagram showing patterns used to write into the flip-flops in the read data mapping circuit in the second embodiment.

FIG. 18 is a diagram showing patterns used to read from the flop-flops in the read data mapping circuit in the second embodiment.

FIG. 19 is a diagram showing a write data mapping circuit in the second embodiment.

FIG. 20 is a diagram showing patterns used to write into flip-flops in the write data mapping circuit in the second embodiment.

FIG. 21 is a diagram showing patterns used to read from the flip-flops in the write data mapping circuit in the second embodiment.

### DETAILED DESCRIPTION OF EMBODIMENTS

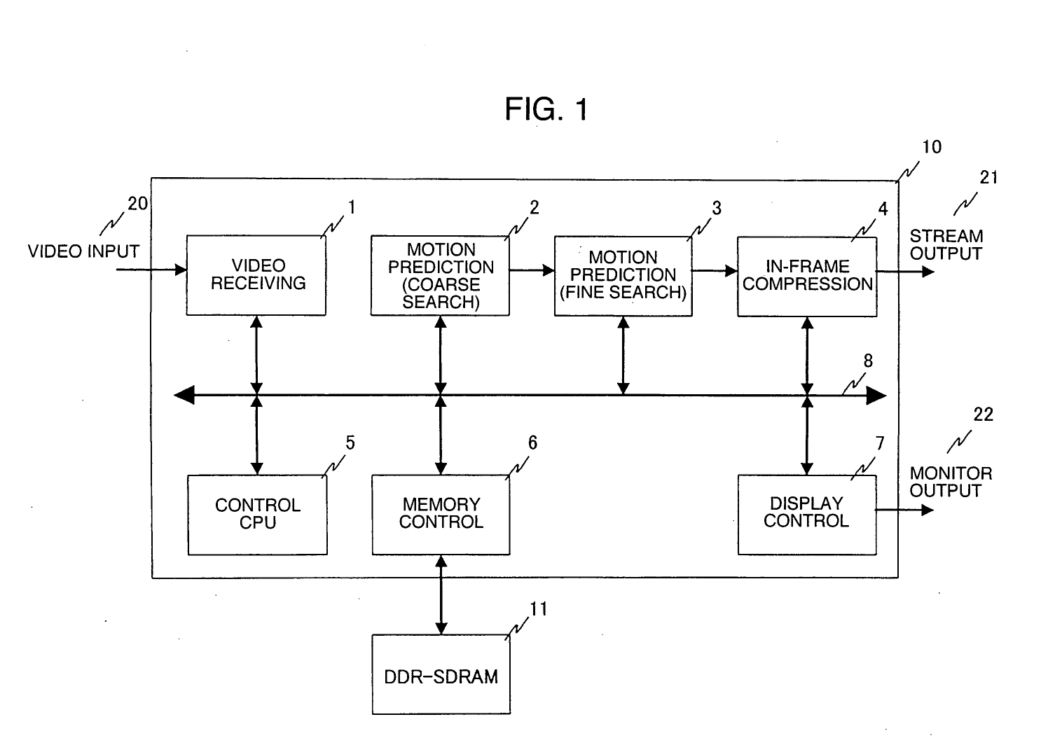

A first embodiment will be described with reference to FIG. 1. Referring to this figure, the numeral 1 indicates a video receiving circuit that receives videos. This circuit captures a digitized video signal 20 and sends the received video signal to an internal bus 8. The numerals 2 and 3 indicate motion prediction circuits that predict the motion of a moving image between frames to search for a motion vector. The numeral 4 indicates an in-frame compression circuit that performs in-frame compression and encoding. This circuit outputs a compressed stream to a stream output 21. The numeral 5 indicates a control CPU that controls the operation of the blocks included in an LSI 10. The numeral 6 indicates a memory control circuit 6 that sends and receives data to and from an external memory 11, and the numeral 7 indicates a display control circuit that outputs a monitor image to a monitor output 22. The video receiving circuit 1, motion prediction circuits 2 and 3, in-frame compression circuit 4, control CPU 5, memory control circuit 6, and display control circuit 7, installed on the LSI 10, are interconnected via the internal bus 8.

The numeral 11 indicates the external memory 11 that is a DDR-SDRAM in this embodiment. Of course, this memory is not limited to a DDR-SDRAM but may be some other type of memory such as an SRAM.

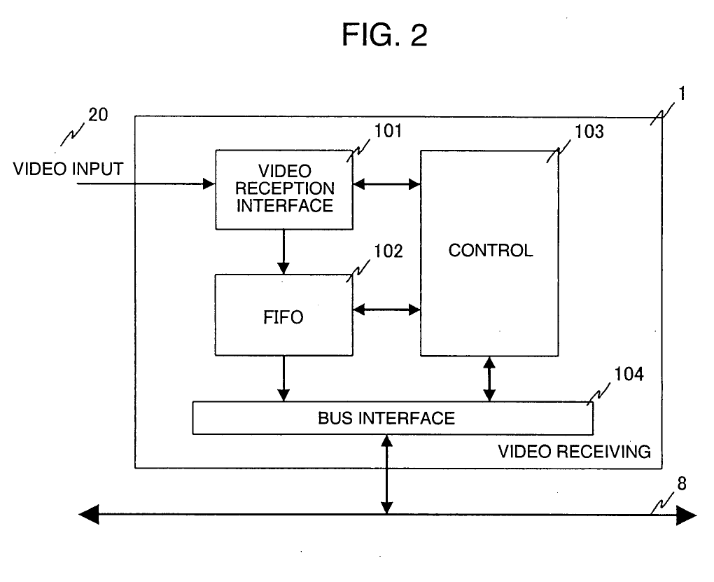

Next, the following describes the video receiving circuit 1 with reference to FIG. 2. Referring to FIG. 2, the numeral 101 indicates a video reception interface circuit. This circuit uses the synchronization information, included in the digitized video input, to extract a frame and, at the same time, divides the video into the brightness components and color-difference components and writes them into a FIFO circuit 102. Note that this processing is not always required. For example, the separation of the color-difference components is not necessary for a monochrome image that has not color-difference components. The data written into the FIFO circuit 102 is stored into the external memory 11 by a bus interface circuit via the internal bus 8 and the memory control circuit 6. This sequence of operations is controlled by a control circuit 103.

Next, the following describes motion prediction performed by the motion prediction circuits 2 and 3. The motion prediction refers to processing for searching the reference frame for a small area most similar to a small area in the current frame. In the description below, this small area is referred to as a macro block. Although it is assumed in this embodiment that the reference frame is a frame earlier than the current frame, it is also possible that the reference frame is a later frame as in the standard image compression algorithm or that the reference frame is composed of multiple frames. The motion prediction processing extracts an area, equal in size to the small area in the current frame, from the reference frame and calculates an evaluation value that indicates the similarity between the corresponding pixels. There are many methods for calculating the evaluation value. In this embodiment, the evaluation value is the sum of the absolute values of the differences between the corresponding pixel values. It should be noted that the processing of this embodiment does not depend on the calculation method of the evaluation value. The same calculation is performed repeatedly while changing the selection area in the reference frame until the position where the evaluation value is the minimum, that is, the position where the similarity is the highest, is found. The difference between the coordinates of the area in the reference frame where the evaluation value is the minimum and the coordinates of the area in the current frame is the motion vector.

Because this processing requires a large calculation amount, several methods have been tried to reduce the calculation amount. This embodiment uses the hierarchical search that is one of those methods.

For convenience of description, assume that the macro block is composed of 16×16 pixels and that the search range in the reference frame is composed of 512×512 pixels. Note that this embodiment does not depend on those values. Because one macro block is composed of 256 pixels in this case, 256 times of subtractions, absolute value calculations, and sum-calculation additions are required to calculate one evaluation value. If this evaluation value calculation is performed, once for each pixel, for the macro blocks included in the 512×512 area while shifting from one coordinate point to another, the total of (512−16)×(512−16)=246016 evaluation values must be calculated. The difference between the coordinates of the macro block in the reference frame where the evaluation value is the minimum and the coordinates of the target macro block is the motion vector. That is, for the subtraction only, the operations must be performed as many as 256×246016 times for one macro block of the target image.

The hierarchical search, designed to reduce the calculation amount, is performed in the following two stages. First, a coarse motion vector is calculated using thinned data of the target macro block in the current frame and thinned data of the reference frame. After that, a motion vector is calculated on a pixel basis for the neighboring areas using non-thinned data. The calculation performed first for finding a coarse motion vector is called a coarse search, while the calculation performed later for finding a motion vector on a pixel basis is called a fine search. The fine search is sometimes performed for the resolution level of one pixel or lower, and this embodiment is also applicable in such a case.

In this embodiment, data is thinned on a pixel basis. In this case, a thinned macro block is composed of 4×4 pixels, meaning that 16 times of subtractions, absolute value calculations, and sum-calculation additions are required to calculate one evaluation value. After thinning, the size of an area for calculating the evaluation value in the thinned reference frame is 256×256, meaning that (256−4)×(256−4)=63504 evaluation values are calculated. The number of times the subtraction is performed is 16×63504, which is significantly reduced as compared with that described above. The amount of other calculations, such as that of the absolute value calculation, is also reduced.

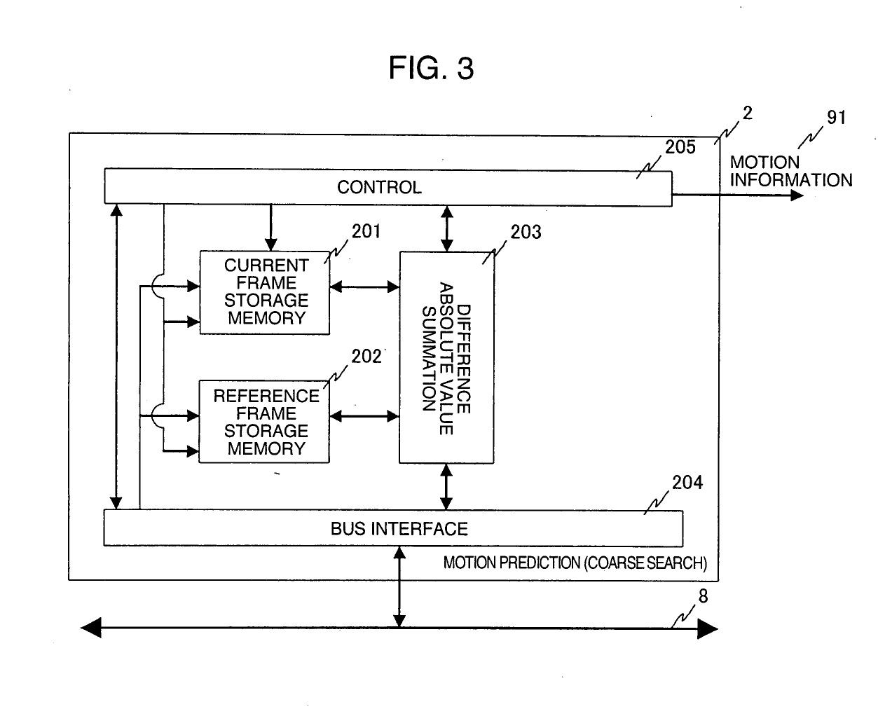

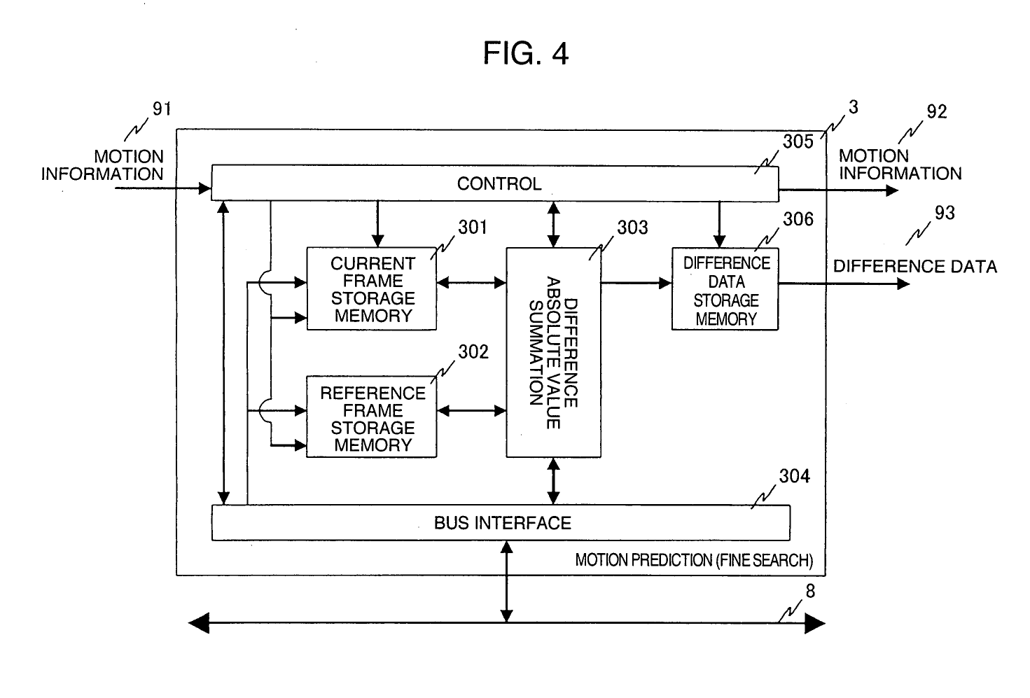

This hierarchical search is executed by the motion prediction circuits 2 and 3. The motion prediction circuit 2 executes the coarse search, while the motion prediction circuit 3 executes the fine search. The following describes the internal structure of those circuits with reference to FIGS. 3 and 4.

FIG. 3 shows the internal structure of the motion prediction circuit 2 that executes the coarse search. A current frame storage memory 201 is a memory in which a macro block, which is the execution target of motion prediction, is stored. A reference frame storage memory 202 is a memory in which the reference frame is stored in part or in whole. The numeral 203 indicates a difference absolute value summation circuit that calculates the sum of the absolute values of the differences of the pixel values, the numeral 204 indicates a bus interface circuit that communicates with the bus 8, and the numeral 205 indicates a control circuit that controls the motion prediction circuit 2. The control circuit 205 controls the bus interface 204 to read the data of the current frame and the reference frame from the external memory 11 and stores the data in the current frame storage memory 201 and the reference frame storage memory 202, respectively. The data that is read at this time is generated by thinning out every other pixel vertically and horizontally. The pixel values read from the memories 201 and 202 are sent to the difference absolute value summation circuit 203 for use in calculating the sum of the difference absolute values that is the evaluation value. The calculated evaluation value is sent to the control circuit 205. The control circuit 205 compares the received evaluation value with the minimum of the evaluation values that were already received. If the received evaluation value is smaller, the control circuit 205 updates the minimum evaluation value and, at the same time, saves the difference between the coordinates of the reference frame that is used and the coordinates of the current frame as the motion vector value. When the search range in the reference frame has been searched completely, the control circuit 205 should store the motion vector value of the target macro block. This value is sent to the motion prediction circuit 3 as motion information 91.

FIG. 4 shows the internal structure of the motion prediction circuit 3 that executes the fine search. A current frame storage memory 301 is a memory in which a macro block, which is the execution target of motion prediction, is stored. A reference frame storage memory 302 is a memory in which the reference frame is stored in part or in whole. The numeral 303 indicates a difference absolute value summation circuit that calculates the sum of the absolute values of the differences of the pixel values, the numeral 304 indicates a bus interface circuit that communicates with the bus 8, and the numeral 305 indicates a control circuit that controls the motion prediction circuit 3. The numeral 306 indicates a memory in which difference values that are the intermediate result of difference absolute value summation are saved.

The control circuit 305 controls the bus interface 304 to read the data of the current frame and the reference frame from the external memory 11 and stores the data in the current frame storage memory 301 and the reference frame storage memory 302, respectively. At this time, the data that is not thinned is read.

The pixel values read from the memories 301 and 302 are sent to the difference absolute value summation circuit 303 for use in calculating the sum of the difference absolute values that is the evaluation value. The calculated evaluation value is sent to the control circuit 305. The control circuit 305 compares the received evaluation value with the minimum of the evaluation values that were already received. If the received evaluation value is smaller, the control circuit 305 updates the minimum evaluation value and, at the same time, saves the difference between the coordinates of the reference frame that is used and the coordinates of the current frame as the motion vector value. At this time, the differences between the pixels of the target block of the current frame and the pixels of the macro block in the reference frame used in the calculation, which is the intermediate result of the difference absolute value summation circuit 303, are stored in the difference data storage memory 306. When the search range in the reference frame has been searched completely, the control circuit 305 should store the motion vector value of the target macro block and the difference data storage memory 306 should store the difference data. The motion vector value is sent to the in-frame compression circuit 4 as motion information 92, and the difference data is sent to the in-frame compression circuit 4 as difference data 93. Note that, when the motion prediction does not improve the compression rate because of a scene change or when the frame is an in-frame encoding frame that is sometimes inserted into a compressed stream, the value stored in the current frame storage memory 301 is transferred directly to the difference data storage memory 306 and is output as the difference data 93.

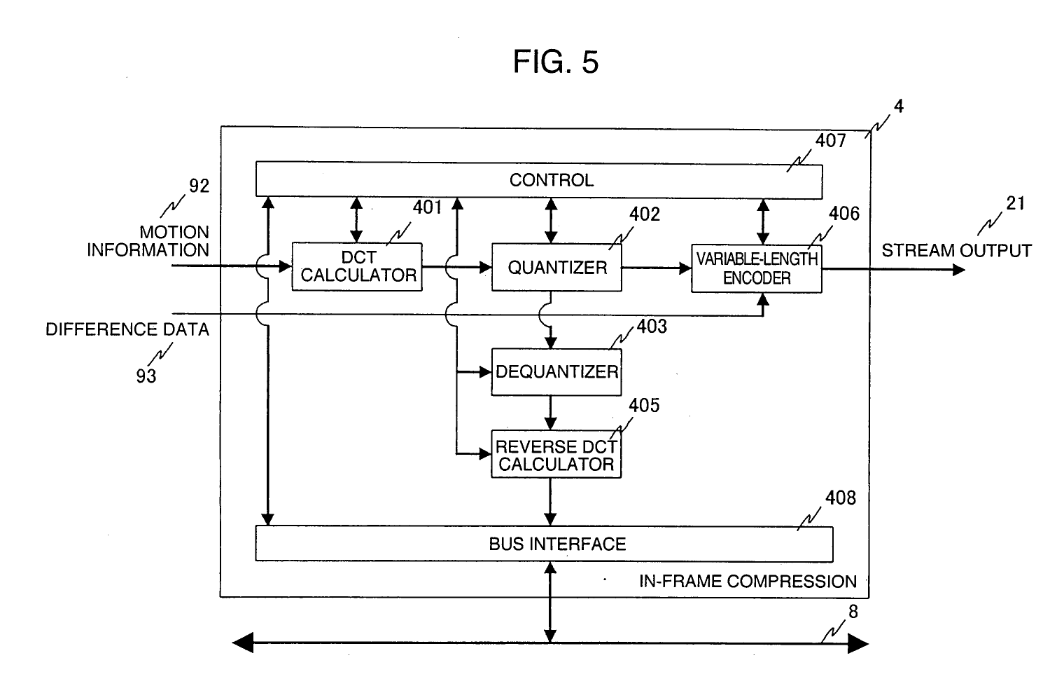

FIG. 5 is a diagram showing the structure of the in-frame compression circuit 4. The circuit shown in the figure is exemplary and this embodiment is not limited to this structure. Referring to this figure, the numeral 401 indicates a DCT calculator that performs DCT calculation, the numeral 402 indicates a quantizer that quantizes data, the numeral 403 indicates a dequantizer 403 that dequantizes data, the numeral 405 indicates a reverse DCT calculator that performs reverse DCT calculation, and the numeral 406 indicates a variable-length encoder that performs variable-length encoding. Those units are controlled by a control circuit 407. The result produced by the variable-length encoder 406 is sent to the stream output 21 as a compressed stream. The output of the reverse DCT calculator 405 is written by a bus interface 408 into the external memory 11 as the local decode result via the internal bus 8 and the memory control circuit 6. The local decode result written in this case is used as the reference frame of the motion prediction processing.

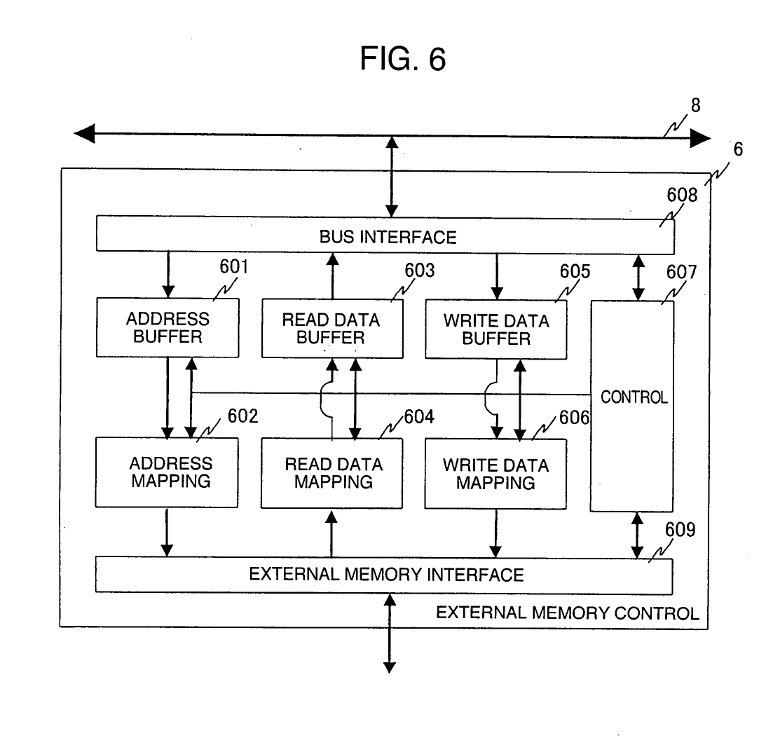

FIG. 6 is a diagram showing the internal structure of the external memory control circuit 6. Referring to this figure, the numeral 608 indicates a bus interface used to communicate with the internal bus 8 and the numeral 609 indicates an external memory interface used to access the external memory. The numeral 601 indicates an address buffer 601 in which an address sent from the internal bus 8 is stored temporarily, and the numeral 602 indicates an address mapping circuit that exchanges the address bit positions. The address mapping circuit exchanges the address bit positions to improve the locality of access addresses and to improve the hit ratio in the DRAM ROW cache. The address exchange method is specified by a control circuit 607, and it is also possible not to exchange the bit positions at all. The numeral 603 indicates a read data buffer in which data read from the external memory is saved temporarily, the numeral 604 is a read data mapping circuit 604 that exchanges the data positions of data read from the external memory, the numeral 605 indicates a write data buffer in which data to be written into the external memory is saved temporarily, and the numeral 606 indicates a write data mapping circuit 606 that exchanges the data positions of data to be written into the external memory. Those units are controlled by the control signal generated by the control circuit 607. The order of the buffers and the mapping circuits is not limited to the one shown in the figure but may be changed.

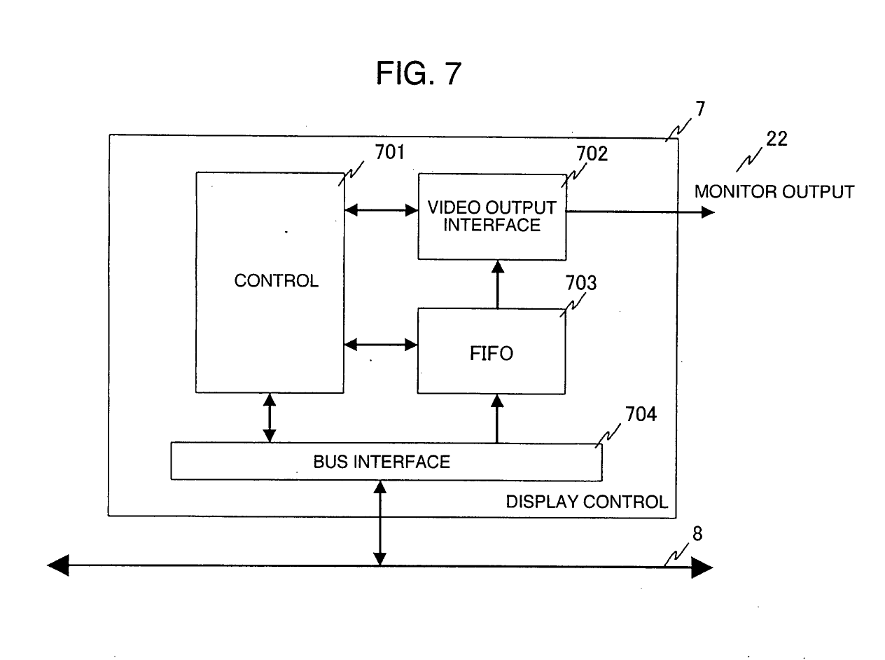

FIG. 7 is a diagram showing the internal structure of the display control circuit 7. Referring to this figure, the numeral 701 indicates a control circuit, the numeral 702 indicates a video output interface that converts the image data to a format suitable for display and outputs the converted data to the monitor output 22, the numeral 703 indicates a FIFO circuit in which display data is once accumulated, and the numeral 704 indicates an interface circuit that acts as an interface with the internal bus 8.

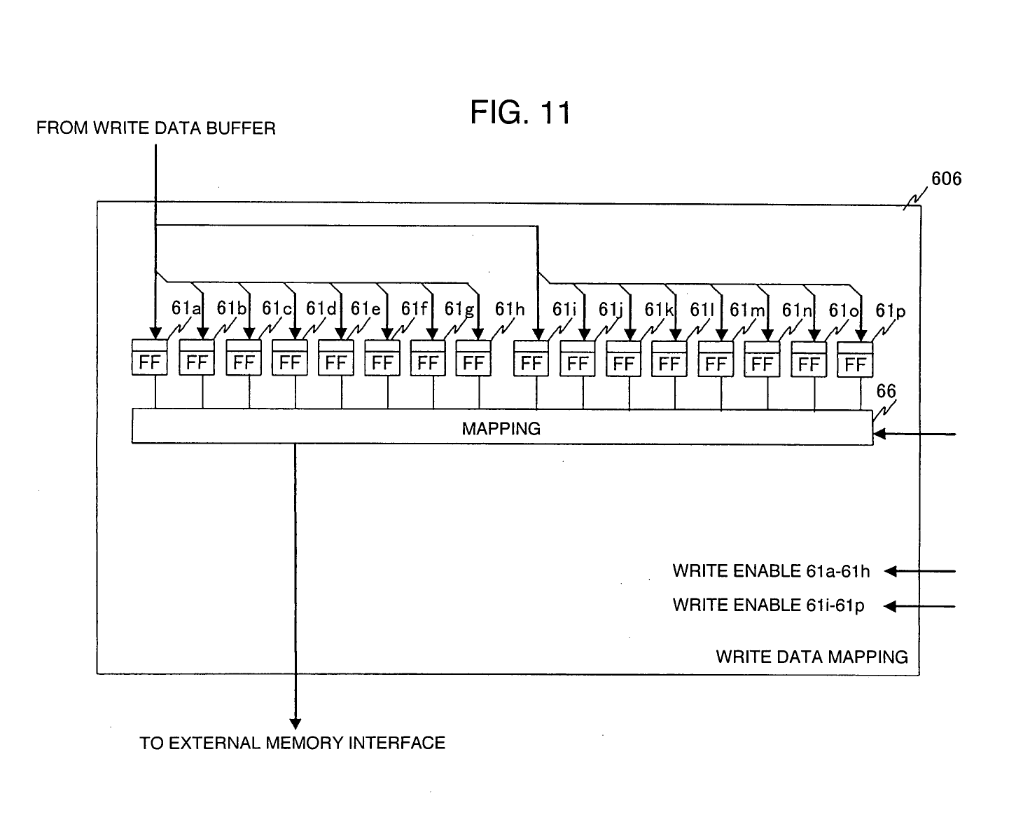

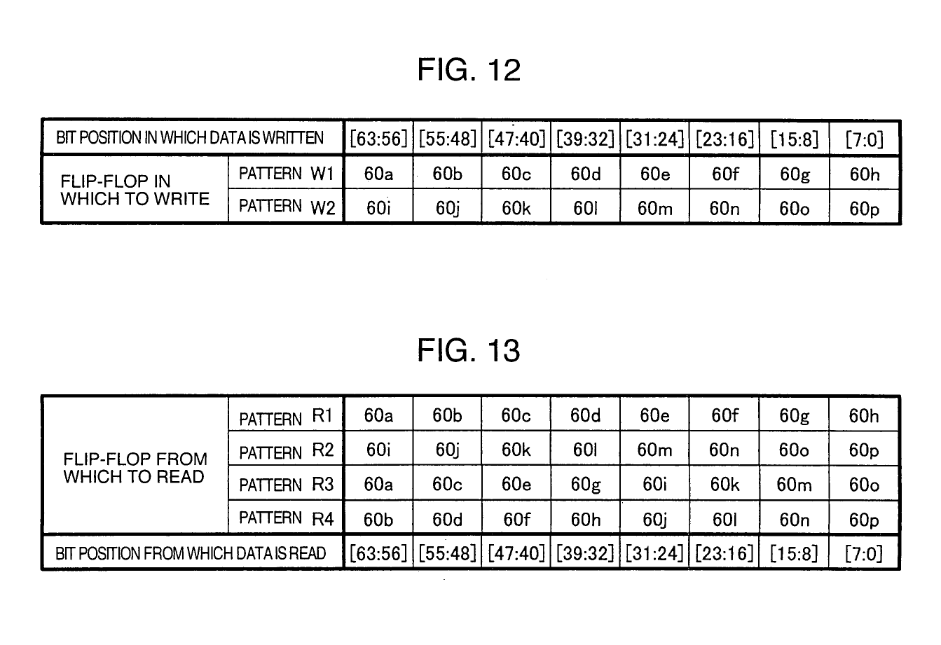

Next, the following describes how the hierarchical searched is performed. The reference image to be used for the motion vector search is generated by the in-frame compression circuit 4 and written into the external memory 11 via the internal bus 8 and the memory control circuit 6. At this time, the write data mapping circuit 606 in the memory control circuit 6 exchanges the positions of data. The following describes this processing with reference to FIGS. 11, 12, and 13. In this embodiment, the data width of the internal bus and the external memory bus is assumed all to be 64 bits. Note that this embodiment is not limited to this width. The 64-bit data read from the write data buffer 605 is written into a part of flip-flops 61a-61p using one of the two patterns shown in FIG. 12. Each flop-flop is 8 bits wide and, therefore, the total number of bits of the flip-flops 61a-61p is 128 bits. In pattern W1, the high-order 8 bits of the 64-bit data read from the write data buffer 605 are written into the flip-flop 61a, the next 8 bits into the flip-flop 61b, and so on, as shown in FIG. 11. Similarly, in pattern W2, the high-order 8 bits of the 64-bit data read from the write data buffer 605 are written into the flip-flop 61i, the next 8 bits into flip-flop 61j, and so on. The write patterns are controlled by the signals generated by the control circuit 607, such as the write signal sent to the flip-flops 61a-61p and the switching signal used by a selector 66.

In this embodiment, the data in a reference frame is represented in the plane format, and one pixel is assumed to be composed of 8 bits with each component corresponding to a plane. That is, when the leftmost area of an image is accessed, the 0th pixel from the left occurs in bits [63:56] of the data read from the write data buffer 605, the first pixel occurs in bits [55:48], and so on. When the patterns W1 and W2 are applied sequentially to the 16 pixels of horizontally consecutive data, the 16 pixels of horizontal data are written sequentially into the flip-flops 61a-61p beginning at the leftmost position of the image. When this image is sequentially read using patterns R1 and R2 in FIG. 13, the leftmost 8 pixels out of horizontal 16 pixels are read first and, after that, the rightmost 8 pixels are read. On the other hand, when the data is read by sequentially applying patterns R3 and R4, the 8 pixels in the even-numbered positions (0, 2, 4, . . . ) out of 16 horizontal pixels are read first and, after that, the 8 pixels in the odd-numbered positions (1, 3, 5. . . . ) are read.

That is, using patterns W1 and W2 alternately to write data into the flip-flops 61a-61p and using patterns R1 and R2 alternately to read the data from the flip-flops 61a-61p allow the data, received from the internal bus 8, to be sent directly to the external memory 11. This is called a data non-mapping write. On the other hand, using patterns W1 and W2 alternately to write data into the flip-flops 61a-61p and using patterns R3 and R4 alternately to read the data from the flip-flops 61a-61p divide the image data, received from the internal bus 8, into even-numbered position pixels and odd-numbered position pixels and allow the data to be written alternately to the external memory 11. This is called a data mapping write. This embodiment uses the latter write method, that is, the data mapping write, to write a reference frame into the external memory 11. As a result, the pixels in the even-numbered positions are stored in external memory addresses divisible by 16, and the pixels in odd-numbered positions are stored in addresses not divisible by 16 but divisible by 8. Data written by the control CPU 5 is written in the data non-mapping write mode. The write mode is switched by issuing a command to the bus or by referencing the block ID of the source. The mode information is saved temporarily in the register in the control circuit 607 to allow the mode to be selected based on this value.

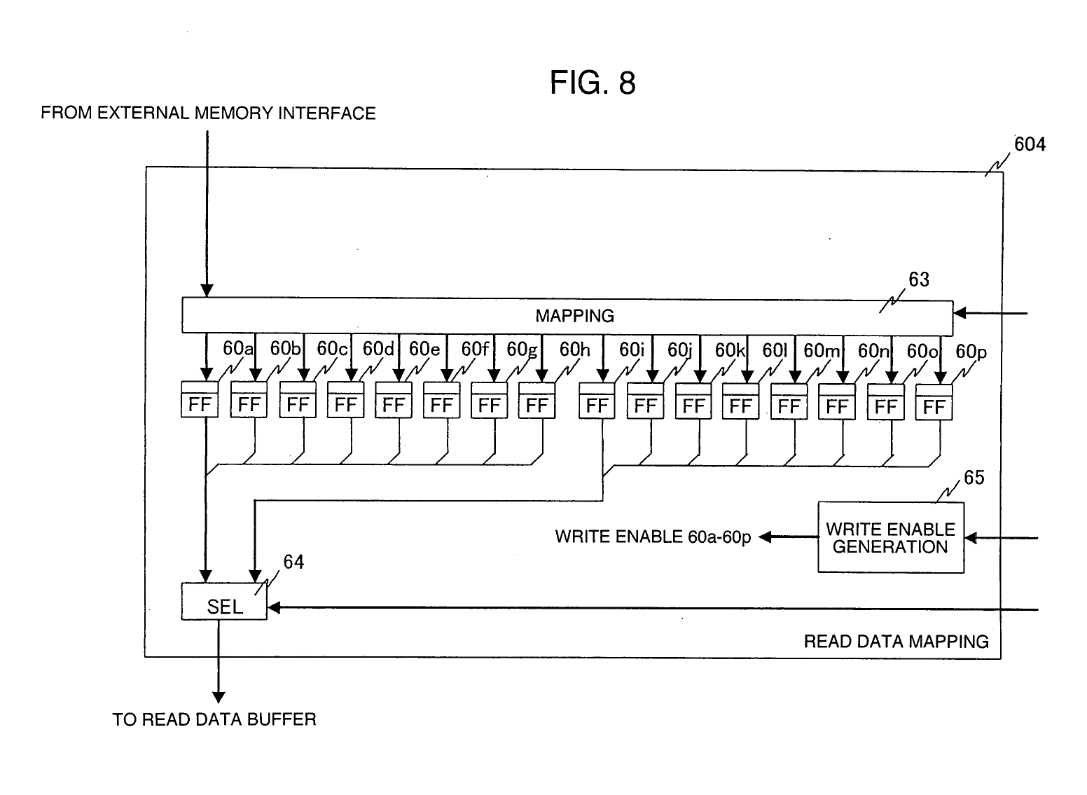

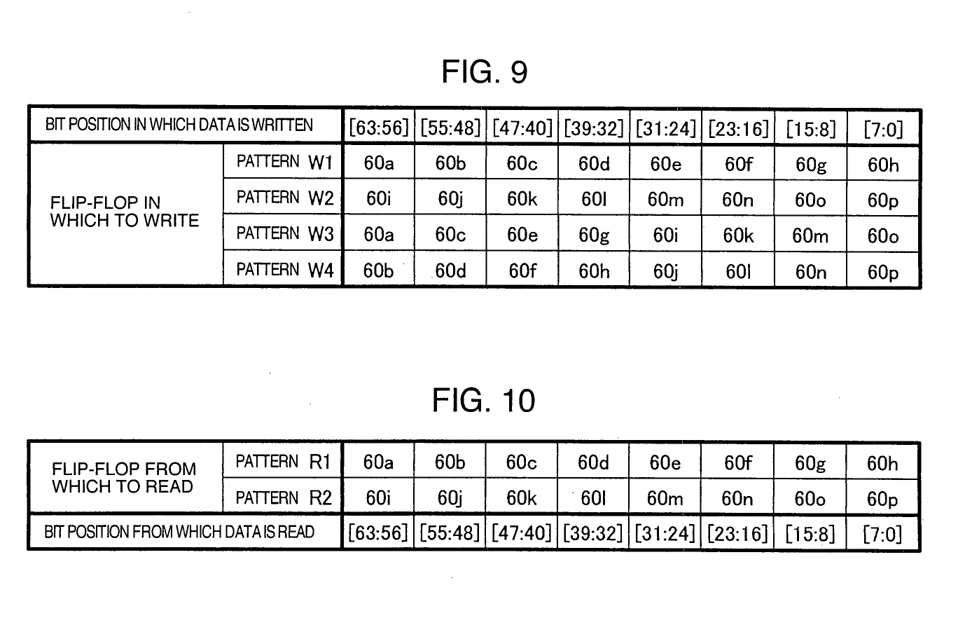

Next, with reference to FIGS. 8, 9, and 10, the following describes how image data stored in the external memory is read. FIG. 8 is a diagram showing the read data mapping circuit 604. Flip-flops 60a-60p, each 8 bits wide, store the total of 128 bits of data. The 64 bits of data, read from the external memory, are sent to the flip-flops 60a-60p by a mapping circuit 63 as shown in FIG. 9 and are written into the corresponding flip-flops, as indicated in FIG. 9, by the flip-flop write signal generated by a write signal generation circuit 65. A selector 64, a circuit for selecting 64 bits of data from the output of the flip-flops 60a-60p, determines its output using one of two patterns shown in FIG. 10. The output of the selector 64 is sent to the read data buffer 603.

Using patterns W1 and W2 alternately to write data into the flip-flops 60a-60p and using patterns R1 and R2 alternately to read the data from the flip-flops 60a-60p allow the data, read from the external memory 11, to be sent directly to the read data buffer 603. This is called a data non-mapping read. In this case, applying the non-mapping read to the image data area written into the external memory 11 in the mapping write mode and increasing the read address by 8 bytes every 16th byte allow only the pixels in the even-numbered positions or only the pixels in the odd-numbered positions to be read. For example, only the pixels in the even-numbered positions can be read by reading data from addresses 0-7, addresses 16-23, addresses 32-39, and so on. Conversely, only the pixels in the odd-numbered positions can be read by reading data from addresses 8-15, addresses 24-31, addresses 40-47, and so on. Because the pixels that are not used are not read from the external memory 11 in those cases, the bandwidth of data transfer between the external memory 11 and the LSI 10 can be saved.

Using patterns W3 and W4 alternately to write data into the flip-flops 60a-60p and using patterns R1 and R2 alternately to read the data allows the data, written by the write data mapping circuit 606 as pixels in even-numbered positions and pixels in odd-numbered positions, to be restored to the original image data. This is called a data mapping read. One of these two read modes, that is, data non-mapping read mode and data mapping read mode, is selected based on the value specified by a bus command from the block that issues the read request to the external memory 11 and stored temporarily in the register in the control circuit 607. In this embodiment, the data non-mapping read is used for an image data read request from the motion prediction circuit 2 and the data mapping read is used for an image data read request from the motion prediction circuit 3.

When the hierarchical search is performed in this embodiment, an image is thinned by half both horizontally and vertically when the motion prediction circuit 2 performs the coarse search. To do so, a reference frame written into the external memory 11 in the mapping write mode is read in the non-mapping mode to read only the pixels in the even-numbered positions or odd-numbered positions. In this case, by reading data every other pixel not only horizontally but vertically, the amount of data transfer between the external memory 11 and the LSI 10 can be reduced to ¼ of the data amount of direct data transfer. The coarse search is performed in this way to find the position where the evaluation value is the minimum and, after that, the motion prediction circuit 3 is used to perform the fine search to search the neighboring areas. The fine search, whose read range is smaller than that used for the coarse search, is required to read the non-thinned image. Because the external memory 11 already stores data written in the mapping mode, a non-thinned image can be obtained by reading data from this area in the mapping mode. The fine search is performed using the obtained image.

A non-thinned data is required also when the display control circuit 7 outputs the monitor image. Therefore, data is read from the frame buffer area in the mapping read mode as when the fine search is performed.

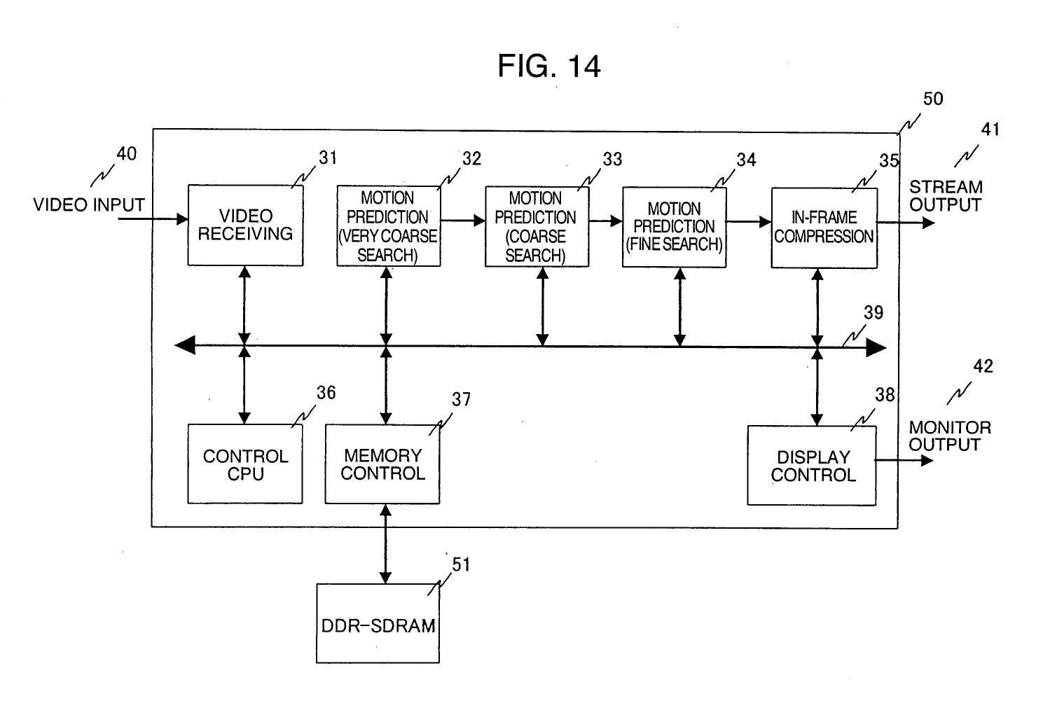

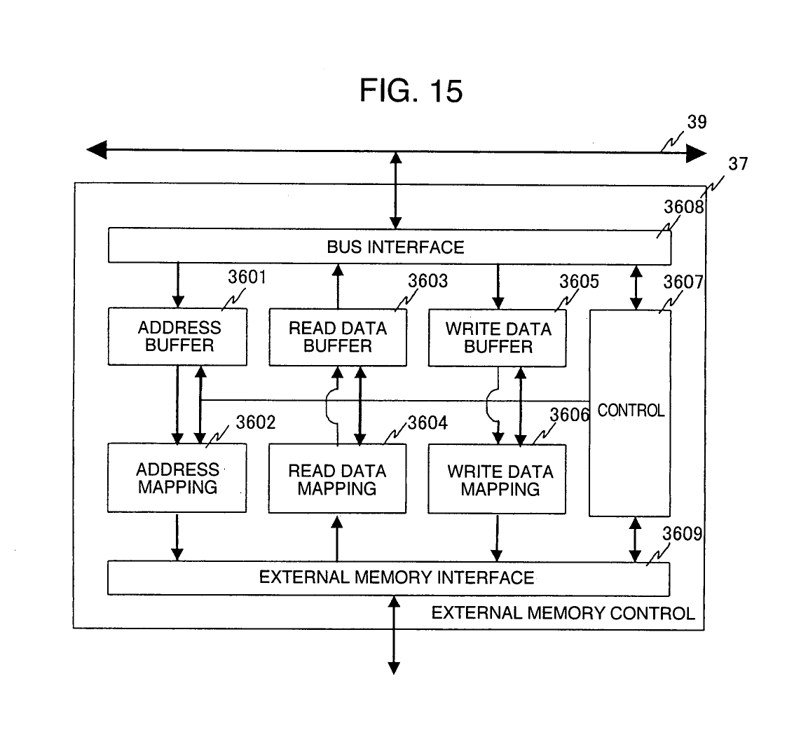

The two-level hierarchical search is performed in the first embodiment where the coarse search using an image generated by thinning every other pixel and the fine search using a non-thinned image are performed, while a second embodiment is applicable to three or higher level search. The following describes this embodiment with reference to FIGS. 14-21. FIG. 14 is a diagram showing a system used in this embodiment. Unlike the first embodiment, the motion prediction is divided into the following three stages: very coarse search, coarse search, and fine search. Every third pixel (one pixel out of four pixels) is used for the very coarse search, every other pixel (one pixel out of two pixels) is used for the coarse search, and all pixels are used for the fine search. The searches are performed by motion prediction circuits 32, 33, and 34, respectively. The general structure of the motion prediction circuits is the same as that of the motion prediction circuits in the first embodiment and so the description is omitted here. A video receiving circuit 31, an in-frame compression circuit 35, a control CPU 36, and a display control circuit 38 are the same as those in the first embodiment. A memory control circuit 37, which performs processing corresponding to the three-level hierarchical search, is different from that in the first embodiment. FIG. 15 shows the internal structure of the memory control circuit 37. The memory control circuit 37 differs greatly from that in the first embodiment in a read data mapping circuit 3604, a write data mapping circuit 3606, and a control circuit 3607. The following describes the structures of those circuits. Note that the description of the implementation method of the control circuit 3607, which is a circuit for generating signals required for those circuits using a state machine, is omitted.

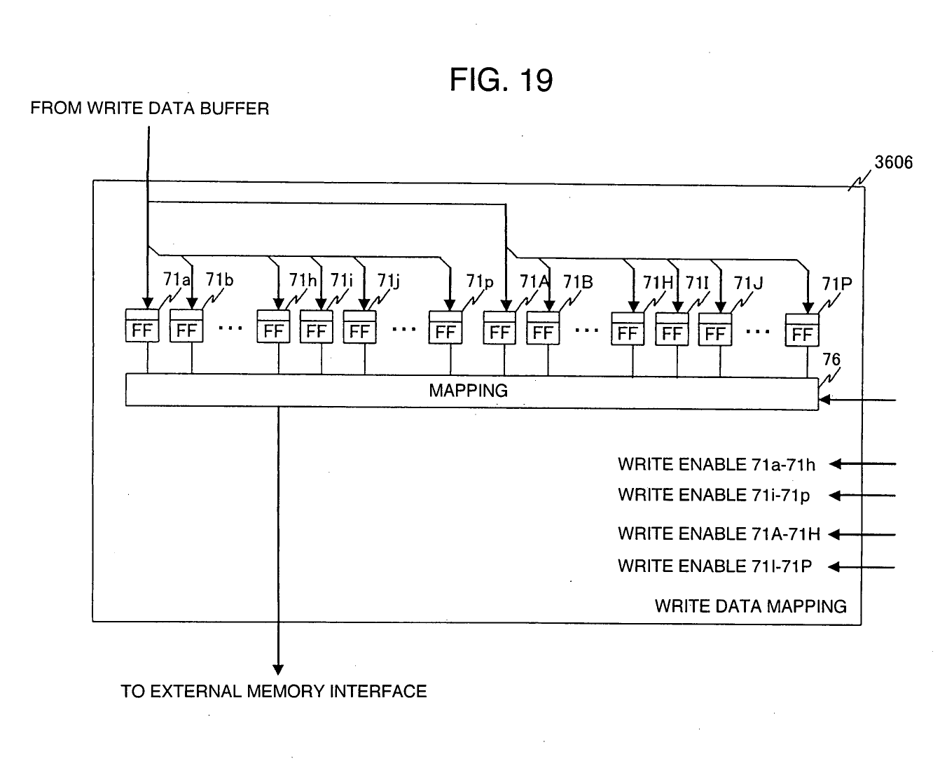

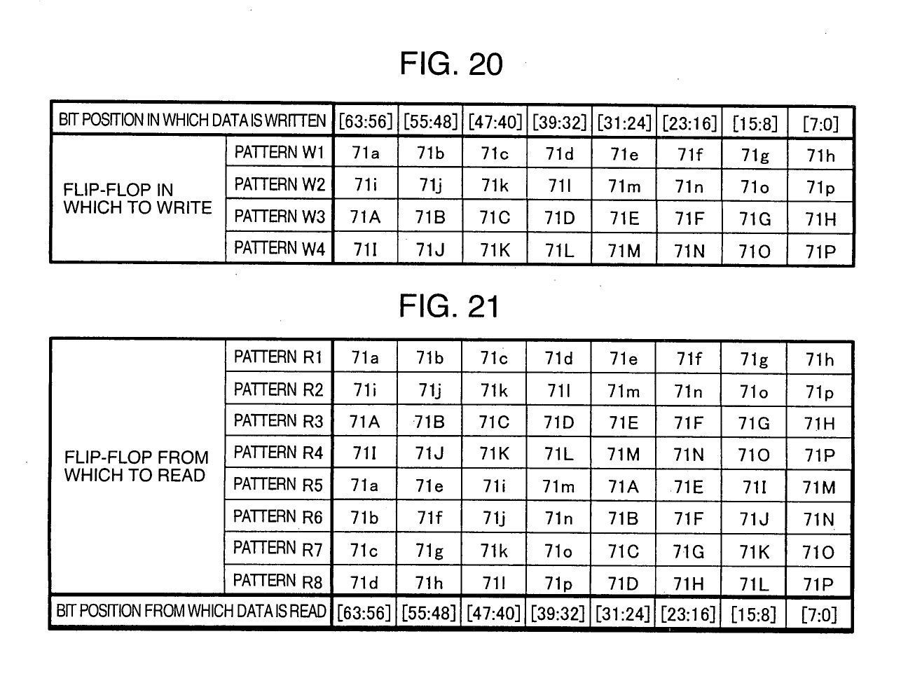

FIG. 19 is a diagram showing the internal structure of the write data mapping circuit 3606. As shown in the figure, the number of flip-flops in the circuit is 256 that is twice as many as that of the first embodiment. FIG. 20 and FIG. 21 are diagrams showing the write patterns and the read patterns for the flip-flops. Although the format of the patterns is similar to the format of the patterns used in the first embodiment, there are four write patterns and eight read patterns in this embodiment. Sequentially applying patterns W1, W2, W3, and W4, shown in FIG. 20, when writing data into the flip-flops 71a-71P and sequentially applying patterns R1, R2, R3, and R4, shown in FIG. 21, when reading the data from the flip-flops 71a-71P allow the data to be written in the non-mapping mode. By contrast, sequentially applying patterns W1, W2, W3, and W4 at write time and sequentially applying patterns R5, R6, R7, and R8 at read time allow the data to be written in the mapping mode.

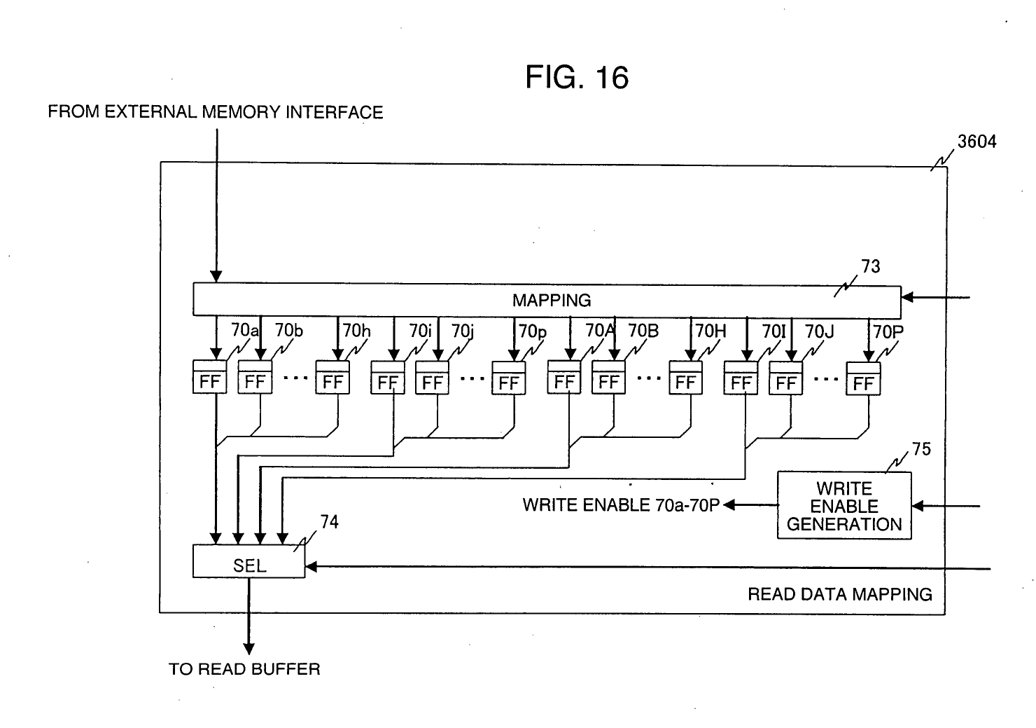

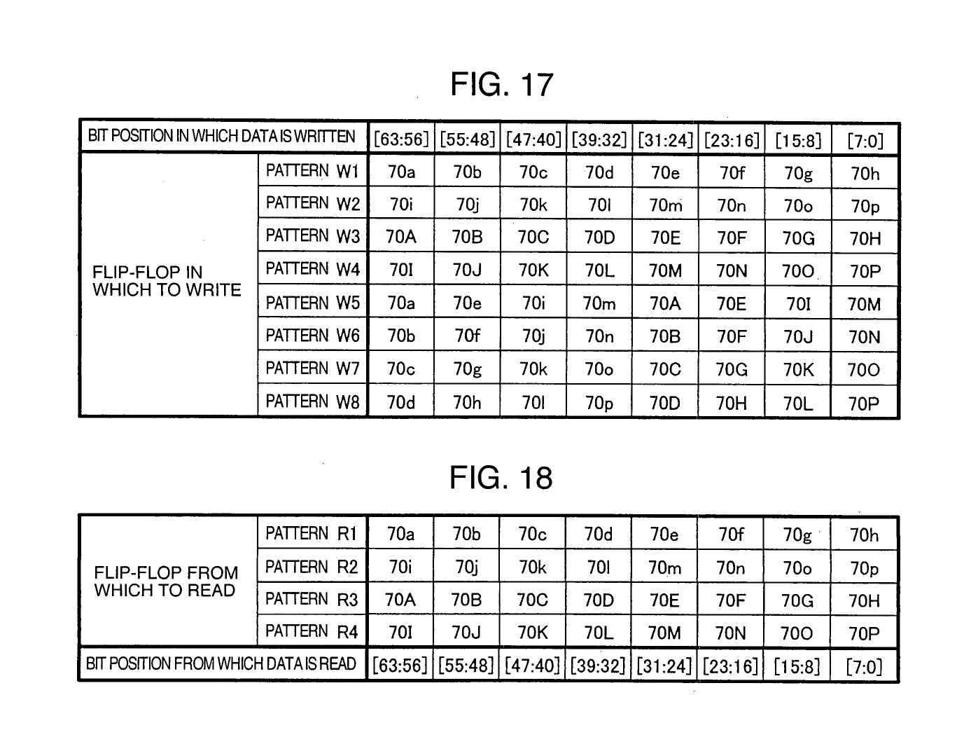

FIG. 16 is a diagram showing the internal structure of the read data mapping circuit 3604. As shown in the figure, the number of flip-flops in the circuit is 256, which is twice as many as that of the first embodiment as for the write data mapping circuit 3606. FIG. 17 and FIG. 18 are diagrams showing the write patterns and the read patterns for the flip-flops. Although the format of the patterns is similar to the format of the patterns used in the first embodiment, there are eight patterns for writing and four patterns for reading in this embodiment. Sequentially applying patterns W1, W2, W3, and W4, shown in FIG. 17, when writing data into the flip-flops 70a-70P and sequentially applying patterns R1, R2, R3, and R4, shown in FIG. 19, when reading the data from the flip-flops 70a-70P allow the data to be read in the non-mapping mode. On the other hand, sequentially applying patterns W5, W6, W7, and W8 at write time and sequentially applying patterns R1, R2, R3, and R4 at read time allow the data to be written in the mapping mode.

In addition, during execution of the non-mapping read, an image can be read every third pixel (one pixel out of four pixels) by reading the image, 8 bytes at a time, while increasing the address by 32 at a time and, similarly, an image can be read every other pixel (one pixel out of two pixels) by reading the image, 8 bytes at a time, while increasing the address by 16 at a time. The very coarse search and the coarse search can be implemented by thinning the image every third pixel or every other pixel not only horizontally but also vertically.

The present invention saves the capacity of external storage and saves the bus bandwidth required for writing a thinned image into external storage.

It should be further understood by those skilled in the art that although the foregoing description has been made on embodiments of the invention, the invention is not limited thereto and various changes and modifications may be made without departing from the spirit of the invention and the scope of the appended claims.

1. An information processing device comprising:
a storage unit in which first data and second data are stored;
a storage control unit that reads the first data and the second data from said storage unit; and
a transfer unit that connects said storage unit and said storage control unit for transferring each of the first data and the second data, wherein
said storage control unit exchanges a predetermined part of the first data for a predetermined part of the second data.

2. The information processing device according to claim 1, wherein
said storage control unit performs the exchange when the first data and the second data are stored in said storage unit.

3. The information processing device according to claim 2, wherein
said storage control unit selects whether or not the exchange is performed when the first data and the second data are read from said storage unit.

4. The information processing device according to claim 3, wherein
said storage control unit comprises at least a register and
said register selects whether or not the exchange is performed when the first data and the second data are read from said storage unit.

5. An information processing device comprising:
a storage unit in which first pixel data and second pixel data are stored, said first pixel data including a plurality of pixels, said second pixel data including a plurality of pixels;
a storage control unit that reads the first pixel data and the second pixel data from said storage unit; and
a transfer unit that connects said storage unit and said storage control unit for transferring each of the first pixel data and the second pixel data, wherein
said storage control unit exchanges predetermined pixels of the first pixel data for predetermined pixels of the second pixel data.

6. The information processing device according to claim 5, wherein
said storage control unit performs the exchange when the first pixel data and the second pixel data are stored in said storage unit.

7. The information processing device according to claim 6, wherein
said storage control unit selects whether or not the exchange is performed when the first pixel data and the second pixel data are read from said storage unit.

8. The information processing device according to claim 7, wherein
said storage control unit performs the exchange at least for each pixel.

9. The information processing device according to claim 7, wherein
said storage control unit comprises at least a register and
said register selects whether or not the exchange is performed when the first pixel data and the second pixel data are read from said storage unit.

10. A data storage method for storing first pixel data and second pixel data into a storage device separately via a transfer unit, said first pixel data including a plurality of pixels, said second pixel data including a plurality of pixels, said data storage method comprising the steps of:
exchanging predetermined pixels of the first pixel data for predetermined pixels of the second pixel data;
transferring the exchanged pixel data to said storage unit via said transfer unit; and
storing the transferred pixel data in said storage unit.
